(19) United States
(12) Patent Application Publication
(10) Pub. No.: US 2012/0012873 A1
(43) Pub. Date: Jan. 19, 2012

(54) LIGHT EMITTING DIODE PACKAGE FOR MICROMINIATURIZATION

(75) Inventor: SHEN-BO LIN, Hukou (TW)

(73) Assignee: ADVANCED OPTOELECTRONIC TECHNOLOGY, INC., Hsinchu Hsien (TW)

(21) Appl. No.: 13/008,820

(22) Filed: Jan. 18, 2011

(30) Foreign Application Priority Data
Jul. 15, 2010 (CN) 201010226691.9

(51) Int. Cl. H01L 33/52; H01L 33/48

(52) U.S. Cl. 257/98; 438/26; 257/E33.059; 257/E33.056; 257/E33.061

(57) ABSTRACT

A light emitting diode package includes a metal thin film with a first surface and a second surface opposite to the first surface. The metal thin film further defines a first part and a second part electrically insulated from the first part. A light emitting diode die is formed on the first part of the metal thin film. The light emitting diode die includes a first electrode and a second electrode. The light emitting diode die is sealed within a glass encapsulation and the second surface of the metal thin film is exposed to the outside of the glass encapsulation for electrically connecting with an external power.

### BACKGROUND

1. Technical Field

The disclosure relates to light emitting diode packages, and particularly to a light emitting diode package for microminiaturization.

2. Description of the Related Art

Light emitting diodes' (LEDs) many advantages, such as high luminosity, low operational voltage, low power consumption, compatibility with integrated circuits, easy driving, long term reliability, and environmental friendliness have promoted their wide use as a lighting source.

Because a substrate thereof is thick, a commonly used light emitting diode package is incompatible with microminiaturization efforts. Moreover, resin utilized as material for encapsulation easily yellows during high temperature process, affecting the light extraction efficiency and lifetime of the light emitting diode.

Therefore, it is desirable to provide a light emitting diode package structure for microminiaturization which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting diode package for microminiaturization. Moreover, in the drawings, like reference numerals designate corresponding parts throughout the views.

FIG. 1 to FIG. 5 are schematic views of a light emitting diode package manufacturing process in accordance with a first embodiment.

FIG. 6 is a schematic view of an anti-reflection film added to the light emitting diode package of FIG. 5.

FIG. 7 is a schematic view of a light emitting diode package in accordance with a second embodiment.

FIG. 8 is a schematic view of a light emitting diode package in accordance with a third embodiment.

FIG. 9 is a schematic view of a light emitting diode package in accordance with a fourth embodiment.

FIG. 10 is a schematic view of an alternative light emitting diode package of FIG. 9.

FIG. 11 is a schematic view of a light emitting diode package in accordance with a fifth embodiment.

FIG. 12 is a schematic view of a light emitting diode package in accordance with a sixth embodiment.

### DETAILED DESCRIPTION

Embodiments of a light emitting diode package as disclosed are described in detail here with reference to the drawings.

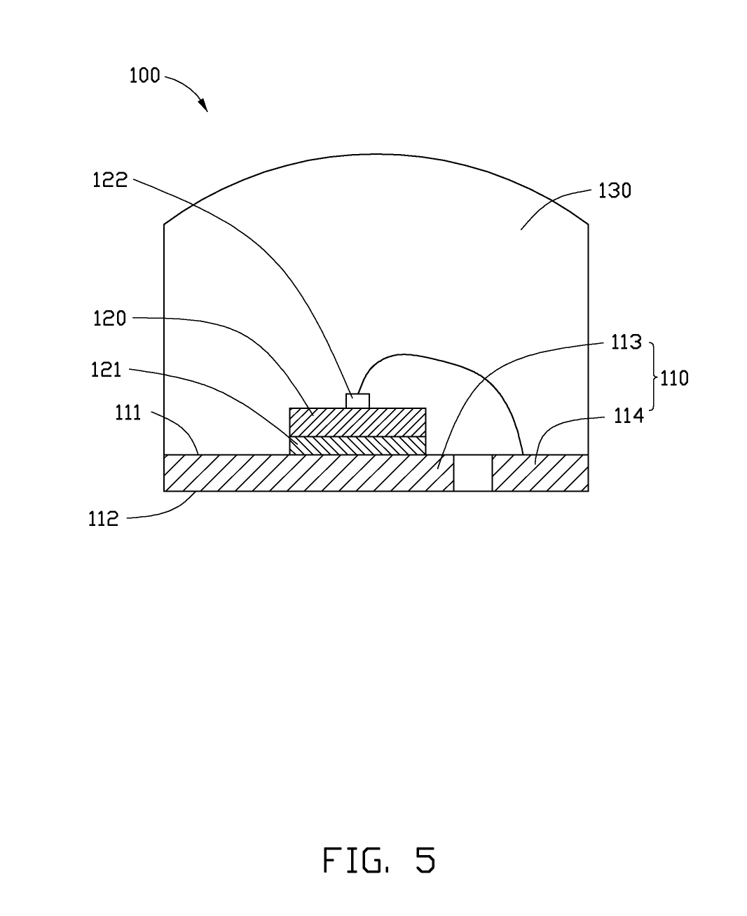

Referring to FIG. 5, a light emitting diode package 100 in accordance with a first embodiment includes a metal thin film 110, a light emitting diode die 120 on the metal thin film 110 and a glass encapsulation 130.

The metal thin film 110 includes a first surface 111 and a second surface 112 opposite to the first surface 111. The metal thin film 110 includes a first part 113 and a second part 114 electrically insulated from the first part 113. The first part of metal thin film 113 and the second part of metal thin film 114 can be two surface mounted external electrodes. The metal thin film 110 can be gold (Au), silver (Ag), copper (Cu), aluminum (Al), tin (Sn), nickel (Ni), cobalt (Co), or an alloy thereof.

The light emitting diode die 120 is mounted on the first surface 111 of the metal thin film 110. In this embodiment, the light emitting diode die 120 is mounted on the first surface 111 of the first part 113 of the metal thin film 110. A first electrode 121 and a second electrode 122 are mounted on two ends of the light emitting diode die 120. The first electrode 121 electrically connects to the first part 113 of the metal thin film 110. The second electrode 122 connects electrically to the second part 114 of the metal thin film 110 by an electrical wire (not labeled). During operation, a driving voltage is applied on the first electrode 121 and the second electrode 122, and the light emitting diode 120 is turned on. According to requirements, arrangement of the light emitting diode die 120 is not limited to this embodiment. For example, the light emitting diode die 120 can be directly mounted on the metal thin film 110 by flip chip or eutectic structure.

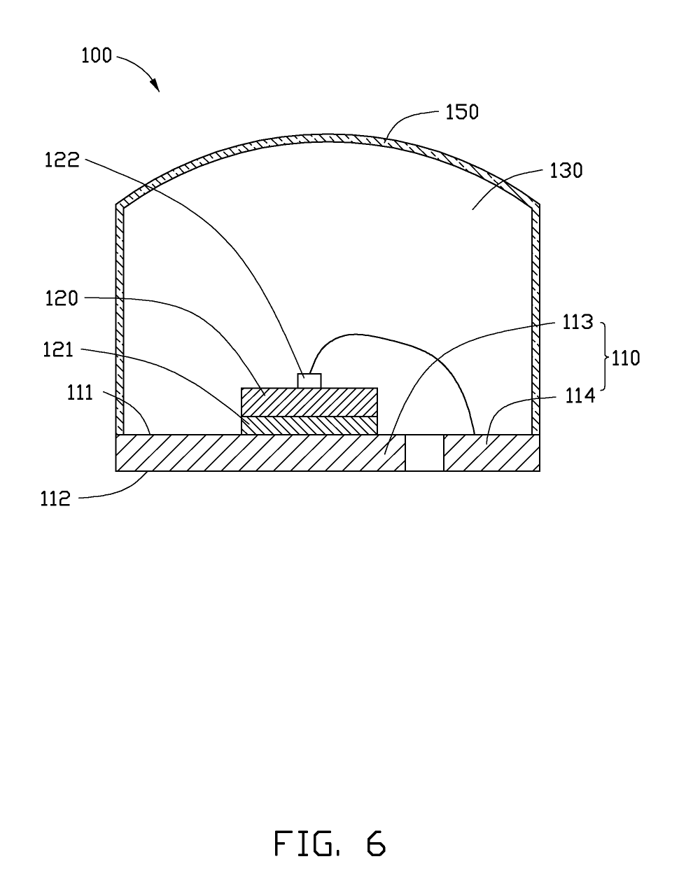

The glass encapsulation 130 encapsulates the light emitting diode die 120 mounted on the metal thin film 110. The second surface 112 of the metal thin film 110 is exposed to the outside of the glass encapsulation 130. Thus, the first part 113 of the metal thin film 110 and the second part 114 of the metal thin film 110 can connect electrically and efficiently with outside power for activating the light emitting diode die 102 to generate light. The glass encapsulation 130 can be SiO₂ or NaO.nSiO₂ (n>0). Preferably, an anti-refection layer 150 is coated on the glass encapsulation 130 as shown in FIG. 6. The anti-reflection layer 150 reduces the reflection ratio of an interface between the glass encapsulation 130 and air, enhancing light extraction efficiency. In this embodiment, the anti-reflection layer 150 is an optical film, for example, TiO₂, SiO₂, or Al₂O₃.

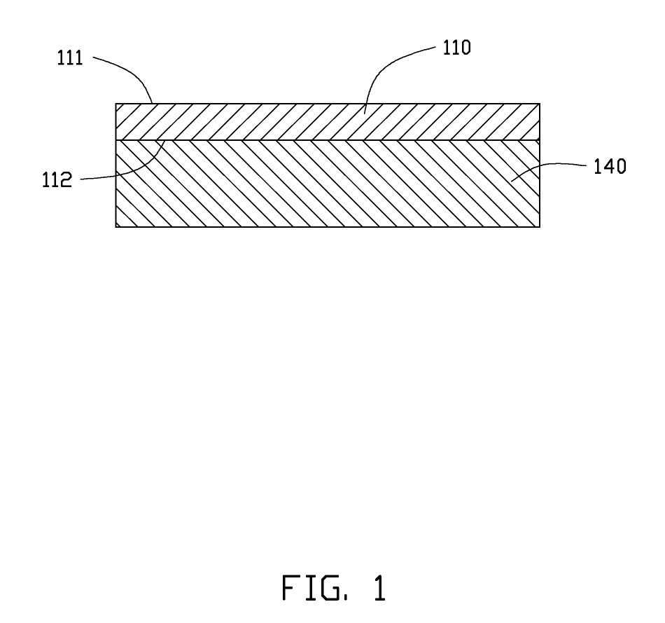

FIG. 1 to FIG. 5 are schematic views of a light emitting diode package manufacturing process in accordance with a first embodiment. Referring to FIG. 1, a substrate 140 is provided. The substrate 140 can be Si, SiC, sapphire, ZnO, metal, or glass. The metal thin film 110 is deposited on a surface of the substrate 140 by sputtering or vacuum evaporation. The metal thin film 110 has the first surface 111 and the second surface 112 opposite to the first surface 111. The second surface 112 contacts the substrate 140. Alternatively, the metal thin film 110 can also be formed on the surface of the substrate 140 by electroplating or screen printing.

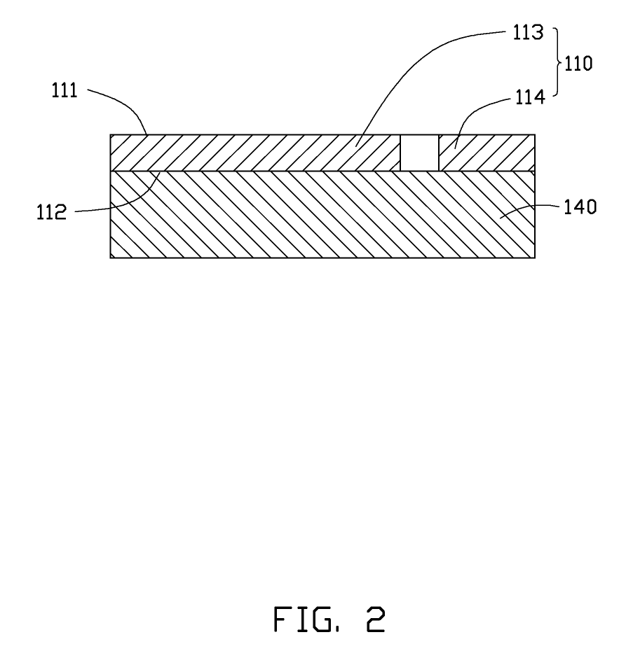

Referring to FIG. 2, the metal thin film 110 is formed as consisting of the first part 113 and the second part 114 electrically insulated from the first part 113 by lithography. A light sensitive layer is coated on the surface of the metal thin film 110, forming a predetermined pattern by lithography. Then, the metal thin film 110 is formed as a corresponding pattern by etching. A SiO₂ barrier layer can also be formed on the surface of the substrate 140 before the sputtering or vacuum evaporation. During the sputtering and vacuum evaporation, the metal thin film 110 is deposited on the area of the substrate 140 not covered by the SiO₂ barrier layer. The corresponding pattern is formed, and the SiO₂ barrier layer removed.

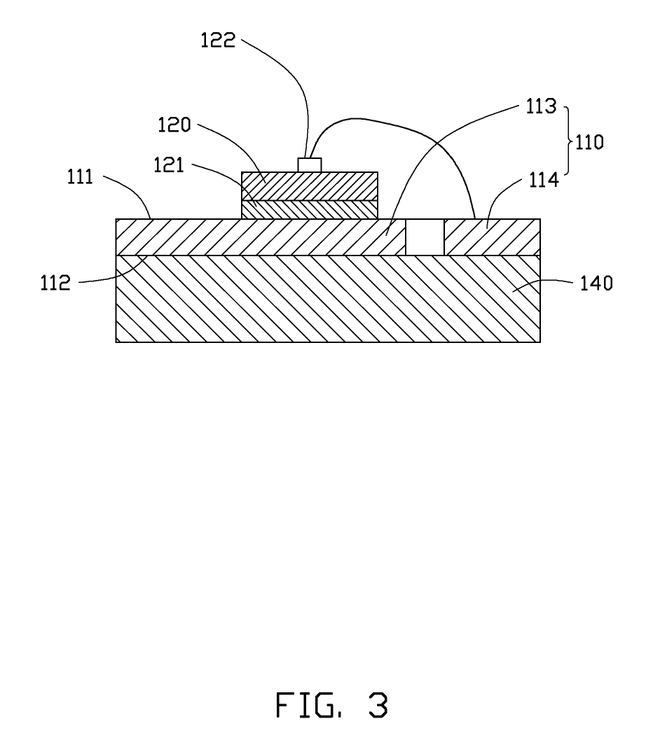

Referring to FIG. 3, the light emitting diode die 120 is mounted on the first surface 111 of the metal thin film 110. The light emitting diode die 120 has the first electrode 121 and the second electrode 122. The first electrode 121 is mounted on the first part 113 of the metal thin film 110 by welding or eutectic method and electrically connected thereby. The second electrode 122 electrically connects the second part 114 of the metal thin film 110 by wire bonding.

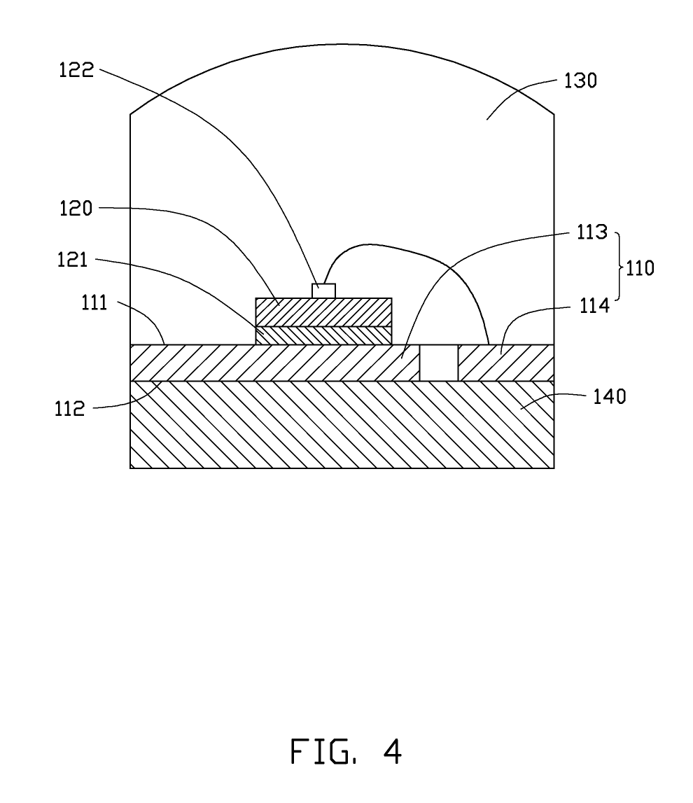

Referring to FIG. 4, the glass encapsulation 130 is formed on the light emitting diode die 120 on the metal thin film 110. In this embodiment, the glass encapsulation 130 is bullet shaped.

Referring to FIG. 5, the substrate 140 is removed by laser cutting, etching, or chemical mechanical polishing, and the second surface 112 of the metal thin film 110 is exposed. The metal thin film 110 is at a bottom of the glass encapsulation 130. The metal thin film 110 is supported by the glass encapsulation 130.

The glass encapsulation 130 is a support structure for light emitting diode die 120. The metal thin film 110 under the glass encapsulation 130 acts as an external electrode of the light emitting diode die 120. Compared to commonly used light emitting diode packages, the light emitting diode package 100 is thin after substrate 140 is removed. Thus, the light emitting diode package 100 is compatible with microminiaturization efforts. The thickness of the light emitting diode package 100 is between 100 μm and 150 μm. The material of the encapsulation for the light emitting diode die 120 is glass, preventing yellowing of the encapsulation.

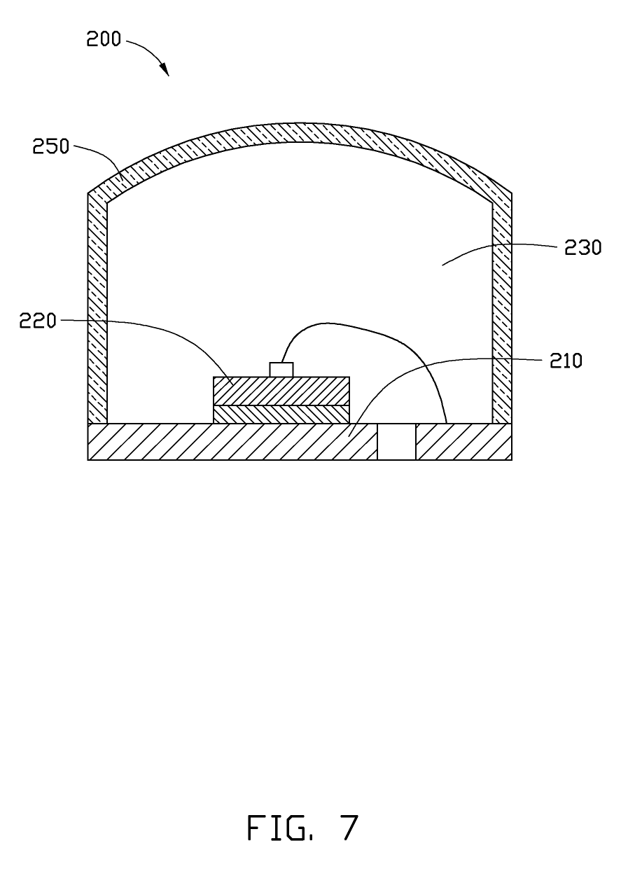

The light emitting diode package is not limited to the described embodiment. Referring to FIG. 7, a light emitting diode package 200 in accordance with a second embodiment includes a metal thin film 210, a light emitting diode die 220 on a surface of the metal thin film 210 and a glass encapsulation 230, differing from the first embodiment only in that the light emitting diode package 200 further includes a fluorescent transformation layer 250. The fluorescent transformation layer 250 can be coated on a surface of the glass encapsulation 230. The material of the fluorescent transformation layer 250 can be YAG, nitride phosphor material, phosphide phosphor material, sulfide phosphor material, or silicate compound. The fluorescent transformation layer 250 can transform the wavelength of light from the light emitting diode die 220 from a first wavelength range to a second wavelength range. For example, a light emitting diode die 220 emitting a blue light combines with the fluorescent transformation layer 250 transforming blue light to yellow light; therefore, the light emitting diode package 200 emits white light or multi-wave light. The fluorescent transformation layer 250 can further include an epoxy, a silicone, or other package material.

The arranged position of the fluorescent transformation layer 250 is not limited to the second embodiment.

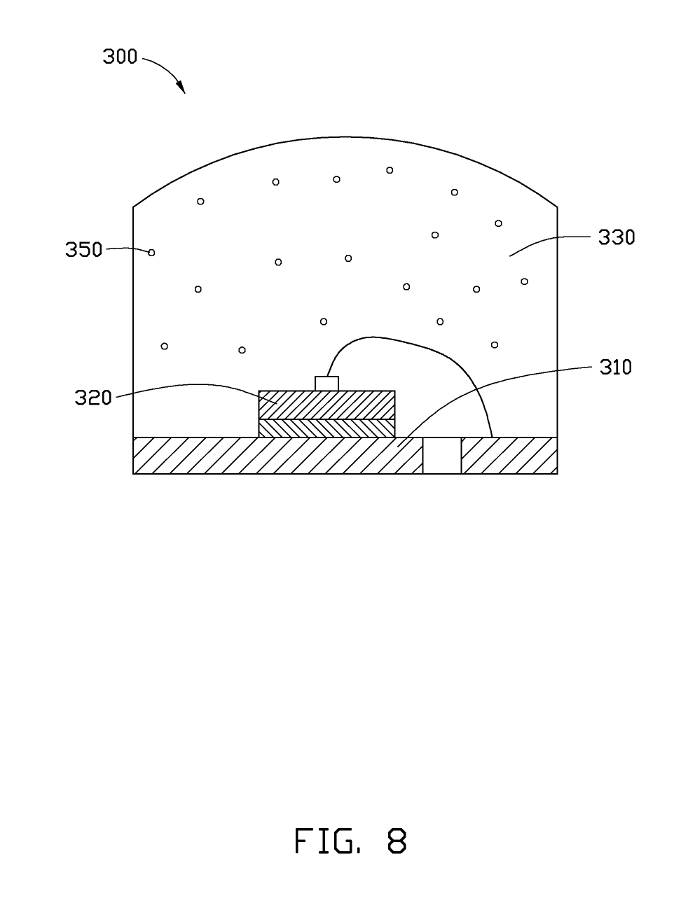

Referring to FIG. 8, a light emitting diode package 300 in accordance with a third embodiment includes a metal thin film 310, a light emitting diode die 320 on a surface of the metal thin film 310, and a glass encapsulation 330, differing from the second embodiment only in that a plurality of fluorescent particles 350 is arranged inside the glass encapsulation 330. During formation of the glass encapsulation 330, the fluorescent particles 350 can be added into the glass material of the glass encapsulation 330. When the glass material solidifies, the fluorescent particles 350 are fixed inside the glass encapsulation 330. In this embodiment, the fluorescent particles 350 are fixed inside the glass encapsulation 330, increasing the stability of the light emitting diode package 300.

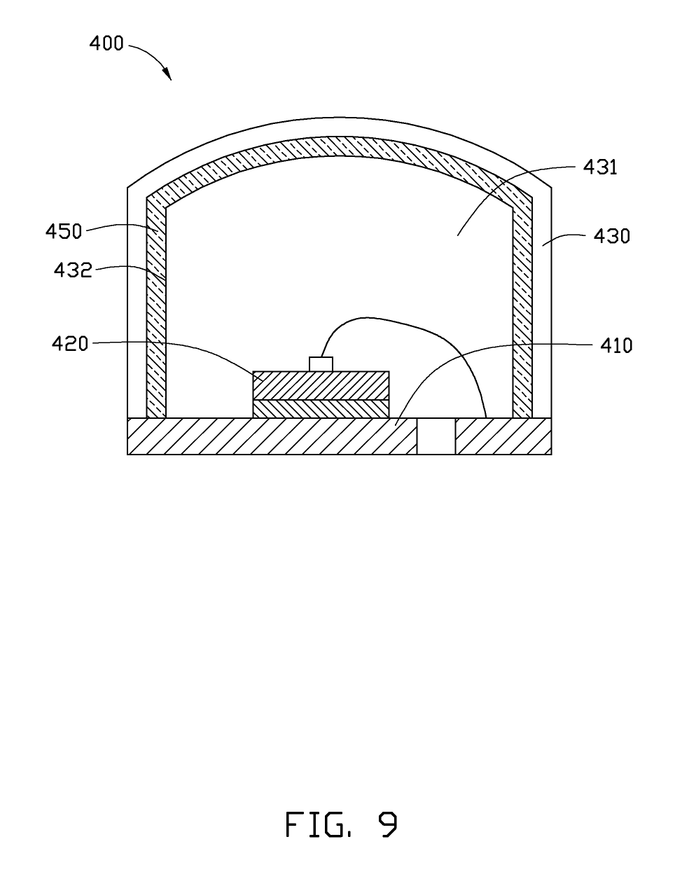

Referring to FIG. 9, a light emitting diode package 400 in accordance with a fourth embodiment includes a metal thin film 410, a light emitting diode die 420 on a surface of the metal thin film 410, and a glass encapsulation 430, differing from the first embodiment only in that a receiving space 431 is defined inside the glass encapsulation 430 and the light emitting diode die 420 is arranged inside the receiving space 431. In the fourth embodiment, the glass encapsulation 430 does not directly contact the light emitting diode die 420. Thus, the light emitting diode die 420 and conductive wires are not affected by temperature of the packaging process. During operation, a protective gas, as nitrogen or inert gas, is filled into the receiving space 431 of the light emitting diode package 400. The protective gas forms a gas isolation layer 432. Thus, the glass encapsulation 430 does not directly contact the light emitting diode die 420. Furthermore, the protective gas avoids a mist entering the receiving space 431. According to needs, a fluorescent transformation layer 450 can be arranged on an inner wall of the glass encapsulation 430 defining the receiving space 431. Thus, quality of the fluorescent transformation layer 450 is not affected by the environment.

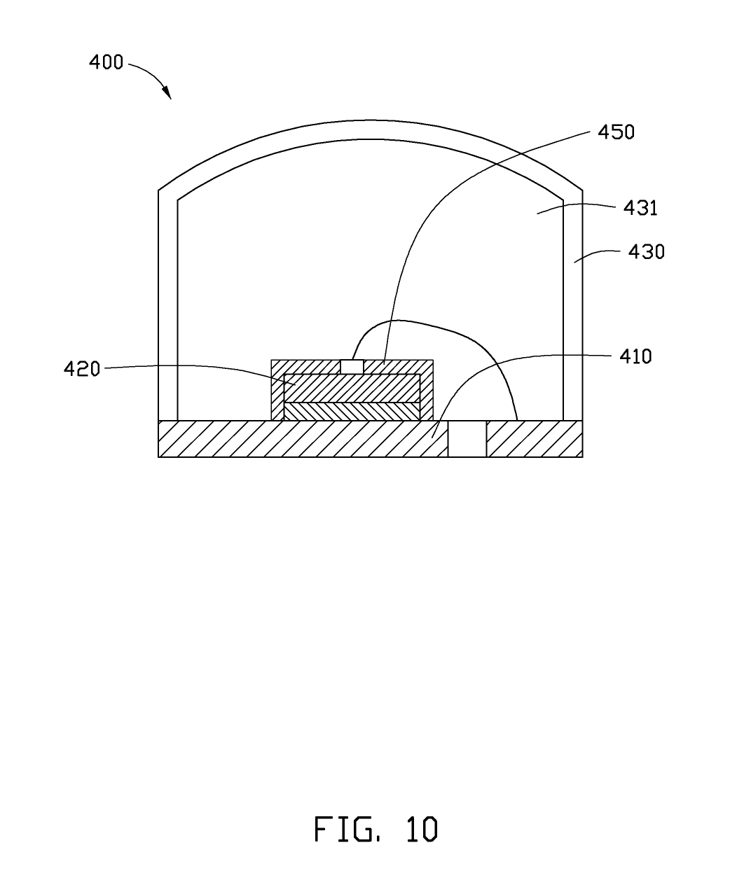

In the fourth embodiment, the fluorescent transformation layer 450 is not limited to arrangement on the inner wall of the glass encapsulation 430 defining the receiving space 431. Referring to FIG. 10, the fluorescent transformation layer 450 covers a surface of the light emitting diode die 420. Light from the light emitting diode die 420 travels through the fluorescent transformation layer 450, and is emitted from the glass encapsulation 430.

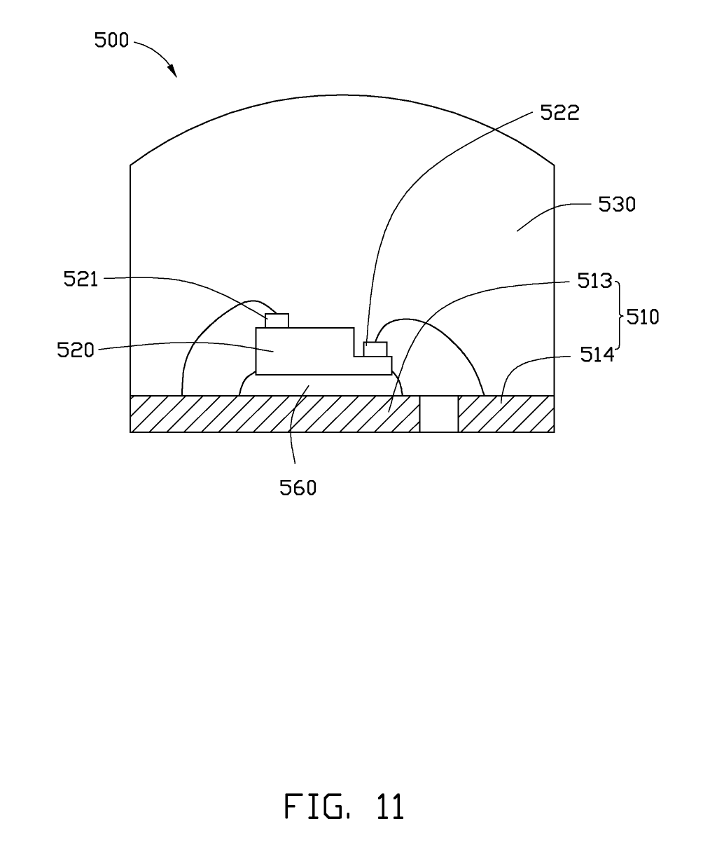

The arrangement of the light emitting diode is not limited to that described. Referring to FIG. 11, a light emitting diode package 500 in accordance with a fifth embodiment includes a metal thin film 510, a light emitting diode die 520 on a surface of the metal thin film 510, and a glass encapsulation 530. The glass encapsulation 530 is bullet shaped. The metal thin film 510 includes a first part 513 and a second part 514 isolated from the first part 513 of the metal thin film 510. The light emitting diode die 520 includes a first electrode 521 and a second electrode 522, differing from the first embodiment only in that the light emitting diode die 520 is arranged on a surface of the first part 513 of the metal thin film 510 by die bonding glues 560. The first electrode 521 and the second electrode 522 of the light emitting diode die 520 are arranged on the same side (i.e., top side) of the light emitting diode die 520. The first electrode 521 connects electrically with the first part 513 of the metal thin film 510 by wire bonding. The second electrode 522 connects electrically with the second part 514 of the metal thin film 510 by wire bonding. The light emitting diode die 520 is arranged on a surface of metal thin film 510 by flip chip or eutectic method.

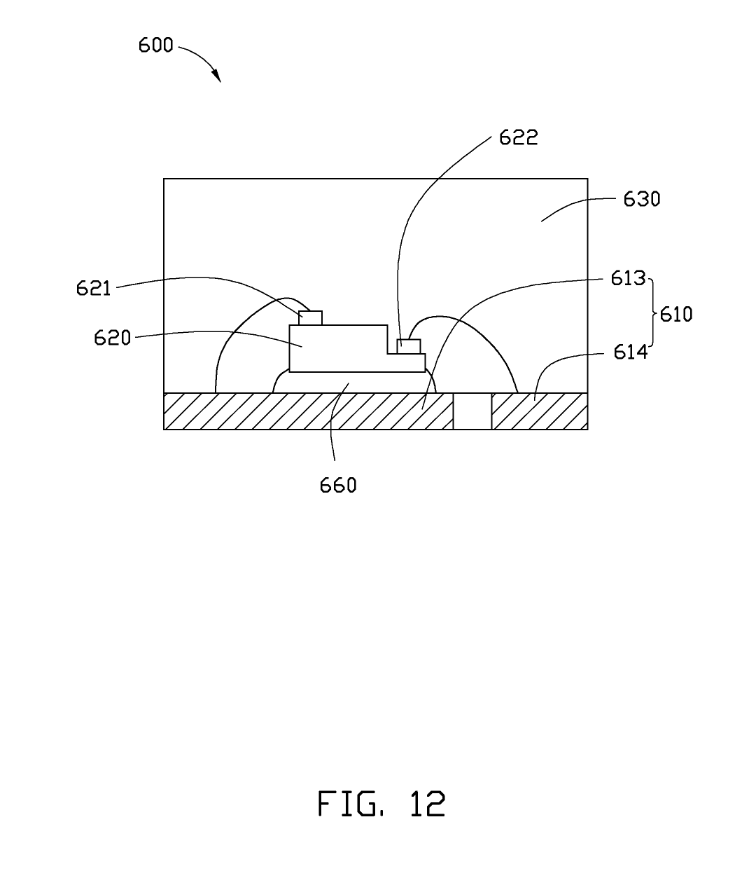

The structure of the glass encapsulation 530 is not limited to that described. Referring to FIG. 12, a light emitting diode package 600 in accordance with a sixth embodiment includes a metal thin film 610, a light emitting diode die 620 on a surface of the metal thin film 610, and a glass encapsulation 630. The metal thin film 610 includes a first part 613 and a second part 614 isolated from the first part 613 of the metal thin film 610. The light emitting diode die 620 is fixed on a surface of the first part 613 of the metal thin film 610 by die bonding glues 660. The first electrode 621 connects electrically with the first part 613 of the metal thin film 610 by wire. The second electrode 622 connects electrically the second part 614 of the metal thin film 610 by wire, differing from the fifth embodiment only in that a light emitting surface of the glass encapsulation 630 is a flat plane. Furthermore, although not shown, a fluorescent transformation layer, as YAG, nitride phosphor material, phosphide phosphor material, sulfide phosphor material or silicates compound, may be arranged on the glass encapsulation 630.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting diode package, comprising:
a metal thin film having a first surface, a second surface opposite to the first surface, a first part, and a second part electrically insulated from the first part;
a light emitting diode on the first surface of the metal thin film having a first electrode electrically connected to the first part of the metal thin film, and a second electrode electrically connected to the second part of the metal thin film; and
a glass encapsulation encapsulating the light emitting diode on the metal thin film with the second surface of the metal thin film exposed and configured for electrically connecting with an external power for activating the light emitting diode to generate light.

2. The light emitting diode package of claim 1, further including a fluorescent transformation layer arranged on a surface of the glass encapsulation.

3. The light emitting diode package of claim 1, wherein the glass encapsulation has a plurality of fluorescent particles distributed therein.

4. The light emitting diode package of claim 1, wherein the glass encapsulation has a receiving space, and the light emitting diode is arranged inside the receiving space.

5. The light emitting diode package of claim 4, wherein a fluorescent transformation layer is arranged on an inner wall of the glass encapsulation defining the receiving space.

6. The light emitting diode package of claim 4, wherein a fluorescent transformation layer is arranged on a surface of light emitting diode.

7. The light emitting diode package of claim 1, wherein the glass encapsulation is SiO₂ or NaO.nSiO₂ (n>0).

8. A method for manufacturing a light emitting diode package including steps:
forming a substrate;
forming a metal thin film on the substrate, the metal thin film having a first surface and a second surface opposite to the first surface and engaging with the substrate, the metal thin film further having a first part and a second part electrically insulated from the first part of the metal thin film;
forming a light emitting diode die on the first surface of the metal thin film, the light emitting diode die having a first electrode connected electrically with the first part of the metal thin film and a second electrode connects electrically with the second part of the metal thin film;
arranging a glass encapsulation on the light emitting diode die; and
removing the substrate to expose the second surface of the metal thin film, the second surface of the metal thin film being configured for connecting with an external power.

9. The method for manufacturing a light emitting diode package of claim 8, wherein a plurality of fluorescent particles is added into the glass encapsulation.

10. The method for manufacturing a light emitting diode package of claim 8, wherein a receiving space is defined inside the glass encapsulation, and a fluorescent transformation layer is arranged on an inner wall of the glass encapsulation defining the receiving space.

11. The method for manufacturing a light emitting diode package of claim 8, wherein a receiving space is defined inside the glass encapsulation, and a fluorescent transformation layer is arranged on a surface of the light emitting diode.

12. The method for manufacturing a light emitting diode package of claim 8, wherein the first part is electrically insulated from the second part of the metal thin film by lithography.
